(19) United States
(12) Patent Application Publication
(10) Pub. No.: US 2015/0138148 A1
(43) Pub. Date: May 21, 2015

(54) TOUCH SIGNAL GAIN CONTROL APPARATUS AND METHOD

(71) Applicant: Raydium Semiconductor Corporation, Hsinchu (TW)

(72) Inventor: Tsung-Yi SU, New Taipei City (TW)

(21) Appl. No.: 14/540,103

(22) Filed: Nov. 13, 2014

(30) Foreign Application Priority Data
Nov. 15, 2013 (TW) 102141711

(51) Int. Cl. G06F 3/044; H03M 1/18

(52) U.S. Cl. CPC G06F 3/044; H03M 1/186
USPC 345/174

(57) ABSTRACT

A touch signal gain control apparatus includes an analog gain stage, a digital gain stage, a gain control module, and a comparing module. The analog gain stage and digital gain stage are coupled to the input terminal and output terminal of an analog-digital converter. When the comparing module generates a comparing result according to a voltage signal inputted to analog gain stage, the gain control module controls analog gain stage to amplify voltage signal in an analog magnification according to comparing result to form an amplified voltage signal not over an input threshold. The analog-digital converter converts amplified voltage signal into a digital signal. The gain control module controls digital gain stage to amplify digital signal in a digital magnification according to comparing result to form an amplified digital signal. The product of analog magnification and digital magnification equals to ratio of amplified digital signal and voltage signal.

### BACKGROUND OF THE INVENTION

1. Field of the Invention

This invention relates to touch signal, especially to a touch signal gain control apparatus and method capable of effectively improving the output saturation problem of the analog-digital converter and maintaining equivalent gain magnification.

2. Description of the Related Art

Please refer to FIG. 1. FIG. 1 illustrates a signal processing structure of the conventional capacitive touch panel. As shown in FIG. 1, the driving signals DR will couple charges to the outputs of the capacitive touch panel TP through the sensing capacitors on the capacitive touch panel TP. At this time, the sensing circuit SC senses the coupled charges on the capacitive touch panel TP and converts them into the voltage signal V1 and outputs the voltage signal V1 to the gain stage GS. Then, the gain stage GS amplifies the voltage signal V1 to form the amplified voltage signal V2 and the analog-digital converter ADC converts the amplified voltage signal V2 into the digital signal V3 and outputs the digital signal V3 to the digital signal processor DSP to calculate the coordinates of the touch points.

In the conventional signal processing structure of the conventional capacitive touch panel, the gain stage GS usually has a fixed magnification and this fixed magnification should be determined according to the signal input range and the quantization error ratio of the analog-digital converter ADC. However, the fixed magnification of the gain stage GS will make the amplified voltage signal outputted by the gain stage GS over the range of the analog-digital converter ADC, and the output saturation of the analog-digital converter ADC will be generated especially in the complicated power environment.

Please refer to FIG. 2A, FIG. 2B, and FIG. 2C. FIG. 2A illustrates a timing diagram of the voltage signal inputted to the gain stage GS; FIG. 2B illustrates a timing diagram of the amplified voltage signal outputted from the gain stage GS to the analog-digital converter ADC; FIG. 2C illustrates a timing diagram of the digital signal outputted by the analog-digital converter ADC. When the voltage signal V1 of FIG. 2A is amplified by the gain stage GS to form the amplified voltage signal V2 of FIG. 2B, a part of the amplified voltage signal V2 will over the input threshold of the analog-digital converter ADC. Therefore, the analog-digital converter ADC will output the digital signal V3 saturated in maximum digital value, some of the digital signal V3 will be lost, it is hard for the digital signal processor DSP to calculate the coordinates of the touch points.

### SUMMARY OF THE INVENTION

Therefore, the invention provides a touch signal gain control apparatus and method to solve the above-mentioned problems.

An embodiment of the invention is a touch signal gain control apparatus. In this embodiment, the touch signal gain control apparatus is applied in a touch sensing apparatus including an analog-digital converter and coupled to an input terminal and an output terminal of the analog-digital converter respectively. The touch signal gain control apparatus includes an analog gain stage, a digital gain stage, a gain control module, and a comparing module. The analog gain stage is coupled to the input terminal of the analog-digital converter. The digital gain stage is coupled to the output terminal of the analog-digital converter. The gain control module is coupled to the analog gain stage and the digital gain stage respectively. The comparing module is coupled between the input terminal of the analog-digital converter and the gain control module. When the comparing module generates a comparing result according to a voltage signal inputted to the analog gain stage and an input threshold of the analog-digital converter, the gain control module controls the analog gain stage to amplify the voltage signal in an analog magnification according to the comparing result to form an amplified voltage signal not over the input threshold, and then the analog-digital converter converts the amplified voltage signal into a digital signal, the gain control module controls the digital gain stage to amplify the digital signal in a digital magnification according to the comparing result to form an amplified digital signal, wherein the product of the analog magnification and the digital magnification equals to a gain ratio of the amplified digital signal and the voltage signal.

In an embodiment, when the comparing result generated by the comparing module is that the product of the voltage signal inputted to the analog gain stage and a default analog magnification is over the input threshold of the analog-digital converter, the gain control module decreases the default analog magnification to the analog magnification according to the comparing result, so that the amplified voltage signal will be not over the input threshold.

In an embodiment, the default analog magnification is the gain ratio of the amplified digital signal and the voltage signal.

In an embodiment, the voltage signal inputted to the analog gain stage is divided into a plurality of voltage sections, the comparing module generates a plurality of comparing results corresponding to the plurality of voltage sections of the voltage signal respectively, the gain control module controls the analog gain stage to amplify the plurality of voltage sections of the voltage signal in a plurality of analog magnifications according to the plurality of comparing results to form a plurality of sections of the digital signal, the gain control module controls the digital gain stage to amplify the plurality of voltage sections of the digital signal in a plurality of digital magnifications according to the plurality of comparing results to form a plurality of sections of the amplified digital signal.

In an embodiment, the product of the analog magnification and the digital magnification is the same for each section and equals to the gain ratio of the section of the amplified digital signal and the section of the voltage signal.

Another embodiment of the invention is a touch signal gain control method. In this embodiment, the touch signal gain control method is applied in a touch sensing apparatus including an analog-digital converter. The touch signal gain control method includes steps of: generating a comparing result according to a voltage signal inputted to the analog-digital converter and an input threshold of the analog-digital converter; amplifying the voltage signal in an analog magnification according to the comparing result to form an amplified voltage signal not over the input threshold; the analog-digital converter converting the amplified voltage signal into a digital signal; and amplifying the digital signal in a digital magnification according to the comparing result to form an amplified digital signal; wherein the product of the analog magnification and the digital magnification equals to a gain ratio of the amplified digital signal and the voltage signal.

Compared to the output saturation problem easily occurred in the sensing circuit structure using fixed magnification of the prior art, the touch signal gain control apparatus and method of the invention uses the comparator to detect the input voltage signal, once the input voltage signal is over the input threshold, the analog magnification of the analog gain stage will be automatically decreased to prevent the output saturation of the analog-digital converter, and then the digital gain stage will be used to amplify the digital signal outputted by the analog-digital converter to compensate the decreased magnification of the analog gain stage. Therefore, the touch signal gain control apparatus and method of the invention can not only effectively improve the output saturation problem of the analog-digital converter in the prior art, but also maintain equivalent gain magnification the same with that of the sensing circuit structure using fixed magnification in the prior art without sacrificing the real magnification of the gain stage.

The advantage and spirit of the invention may be understood by the following detailed descriptions together with the appended drawings.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic diagram of a signal processing structure of the conventional capacitive touch panel.

FIG. 2A illustrates a timing diagram of the voltage signal inputted to the gain stage.

FIG. 2B illustrates a timing diagram of the amplified voltage signal outputted from the gain stage to the analog-digital converter.

FIG. 2C illustrates a timing diagram of the digital signal outputted by the analog-digital converter.

FIG. 3 illustrates a schematic diagram of the touch signal gain control apparatus in an embodiment of the invention.

FIG. 4A illustrates a timing diagram of the voltage signal inputted to the gain stage in FIG. 3.

FIG. 4B illustrates a timing diagram of the amplified voltage signal outputted from the analog gain stage to the analog-digital converter in FIG. 3.

FIG. 4C illustrates a timing diagram of the amplified digital signal outputted by the digital gain stage in FIG. 3.

FIG. 5 illustrates a flowchart of the touch signal gain control method in another embodiment of the invention.

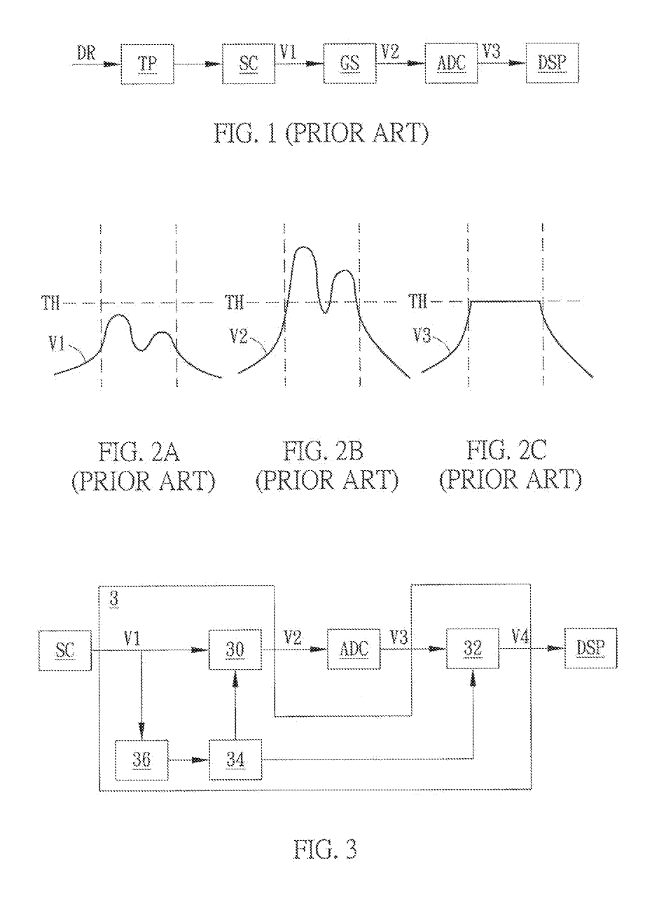

### DETAILED DESCRIPTION

A preferred embodiment of the invention is a touch signal gain control apparatus. In this embodiment, the touch signal gain control apparatus is applied in a touch sensing apparatus to control and adjust the input signals to avoid the output saturation problem of the analog-digital converter occurred in the prior art.

Please refer to FIG. 3. FIG. 3 illustrates a schematic diagram of the touch signal gain control apparatus in this embodiment. As shown in FIG. 3, the touch signal gain control apparatus 3 is coupled between the sensing circuit SC of the touch sensing apparatus and the analog-digital converter ADC and between the analog-digital converter ADC and the digital signal processor DSP. The touch signal gain control apparatus 3 is coupled to the input terminal and the output terminal of the analog-digital converter ADC respectively.

In this embodiment, the touch signal gain control apparatus 3 includes an analog gain stage 30, a digital gain stage 32, a gain control module 34, and a comparing module 36. Wherein, the analog gain stage 30 is coupled to the input terminal of the analog-digital converter ADC; the digital gain stage 32 is coupled to the output terminal of the analog-digital converter ADC; the gain control module 34 is coupled to the analog gain stage 30 and the digital gain stage 32 respectively; the comparing module 36 is coupled between the input terminal of the analog-digital converter ADC and the gain control module 34. In fact, the comparing module 36 can include a comparator matrix, but not limited to this.

After the sensing circuit SC of the touch sensing apparatus senses the coupled charges on the capacitive touch panel and converts them into the voltage signal V1, the sensing circuit SC will output the voltage signal V1 to the analog gain stage 30 of the touch signal gain control apparatus 3. Because the comparing module 36 is coupled between the sensing circuit SC and the analog gain stage 30, the comparing module 36 can receive the voltage signal V1 inputted to the analog gain stage 30.

Then, the comparing module 36 will generate a comparing result according to the e voltage signal V1 inputted to the analog gain stage 30 and the input threshold of the analog-digital converter ADC. In practical applications, the comparing result generated by the comparing module 36 is used to indicate whether the product of the voltage signal V1 inputted to the analog gain stage 30 and a default analog magnification is over the input threshold of the analog-digital converter ADC.

If the comparing result generated by the comparing module 36 is that the product of the voltage signal V1 inputted to the analog gain stage 30 and a default analog magnification is not over the input threshold of the analog-digital converter ADC, it means that the voltage signal V1 inputted to the analog gain stage 30 is not large enough to cause the output saturation of the analog-digital converter ADC occurred in the prior art. Therefore, the default analog magnification of the analog gain stage 30 shouldn't be adjusted.

If the comparing result generated by the comparing module 36 is that the product of the voltage signal V1 inputted to the analog gain stage 30 and a default analog magnification is over the input threshold of the analog-digital converter ADC, it means that the voltage signal V1 inputted to the analog gain stage 30 is large enough to cause the output saturation of the analog-digital converter ADC occurred in the prior art. Therefore, the default analog magnification of the analog gain stage 30 should be adjusted by the gain control module 34 according to this comparing result. For example, if the default analog magnification of the analog gain stage 30 is 2, the gain control module 34 can adjust it to be a smaller analog magnification (e.g., 1), so that when the analog gain stage 30 amplifies the voltage signal V1 in the smaller analog magnification to form the amplified voltage signal V2 and outputs the amplified voltage signal V2 to the analog-digital converter ADC, the amplified voltage signal V2 will be not over the input threshold of the analog-digital converter ADC, and the input saturation of the analog-digital converter ADC can be effectively avoided.

Then, the analog-digital converter ADC converts the amplified voltage signal V2 into a digital signal V3. It should be noticed that the gain control module 34 not only adjusts the analog magnification of the analog gain stage 30 according to the comparing result, but also adjusts the digital magnification of the digital gain stage 32 according to the comparing result at the same time, and the digital gain stage 32 uses the adjusted digital magnification to amplify the digital signal V3 to form an amplified digital signal V4.

In fact, the product of the analog magnification and the digital magnification is the same the ratio of the amplified digital signal V4 outputted by the digital gain stage 32 and the voltage signal V1 inputted to the analog gain stage 30. That is to say, the increased digital magnification used by the digital gain stage 32 will compensate the decreased analog magnification used by the analog gain stage 30 to maintain the magnification of the entire gain stage of the touch signal gain control apparatus 3 equal to the fixed magnification used by the conventional sensing circuit structure without sacrificing the real magnification of the gain stage. For example, if the analog magnification used by the analog gain stage 30 is adjusted from 2 to 1, the digital magnification used by the digital gain stage 32 can be adjusted from 1 to 2 to do compensation. As a result, the amplified digital signal V4 outputted by the digital gain stage 32 will be two times as large as the voltage signal V1 inputted to the analog gain stage 30 and no output saturation occurs.

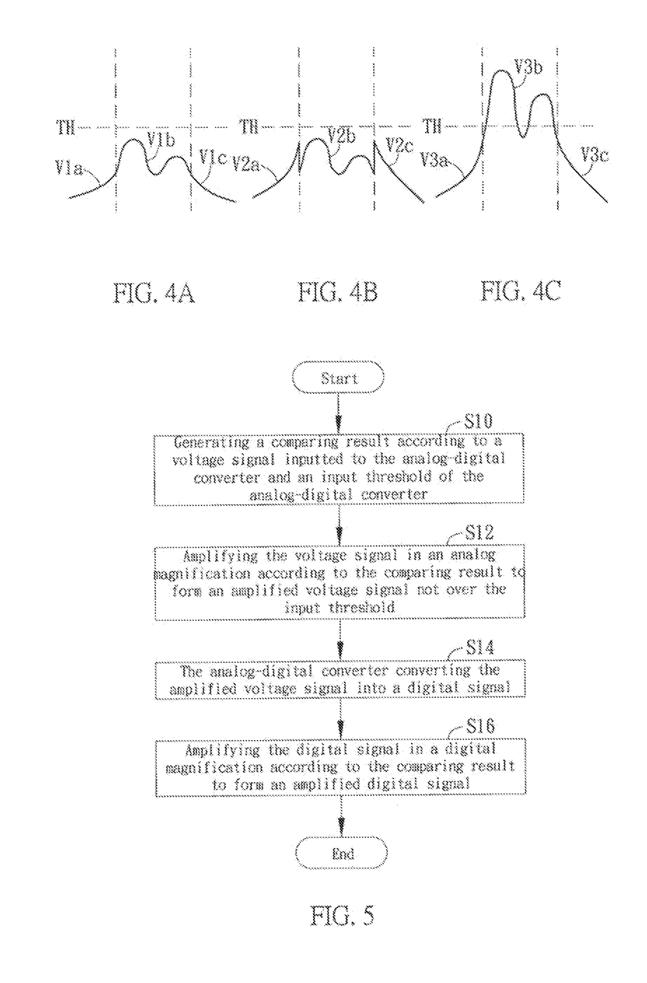

In addition, the touch signal gain control apparatus 3 of the invention can also dynamically adjust the magnifications of different sections of the input signal respectively. Please refer to FIG. 4A, FIG. 4B, and FIG. 4C. FIG. 4A illustrates a timing diagram of the voltage signal V1 inputted to the gain stage 30 in FIG. 3. FIG. 4B illustrates a timing diagram of the amplified voltage signal V2 outputted from the analog gain stage 30 to the analog-digital converter ADC in FIG. 3. FIG. 4C illustrates a timing diagram of the amplified digital signal V4 outputted by the digital gain stage 32 in FIG. 3.

For example, as shown in FIG. 4A, if the voltage signal V1 inputted to the analog gain stage 30 is divided into three voltage sections V1a˜V1c, the comparing module 36 will generate three comparing results corresponding to the three voltage sections V1a˜V1c of the voltage signal V1 respectively, and these three comparing results are: the voltage section V1a multiplied by twice is not over the input threshold of the analog-digital converter ADC; the voltage section V1b multiplied by twice is over the input threshold of the analog-digital converter ADC; the voltage section V1c multiplied by twice is not over the input threshold of the analog-digital converter ADC.

Therefore, as shown in FIG. 4B, the gain control module 34 will adjust three analog magnifications used by the analog gain stage 30 to amplify the three voltage sections V1a˜V1c of the voltage signal V1 according to the three comparing results to form three voltage sections V2a˜V2c of the amplified voltage signal V2 respectively. Since the voltage sections V1a and V1c multiplied by twice are not over the input threshold of the analog-digital converter ADC, the analog gain stage 30 amplifies the voltage sections V1a and V1c of the voltage signal V1 in FIG. 4A by twice to form the voltage sections V2a and V2c of the amplified voltage signal V2 in FIG. 4B. Since the voltage section V1b multiplied by twice is over the input threshold of the analog-digital converter ADC, the analog gain stage 30 amplifies the voltage section V1b of the voltage signal V1 in FIG. 4A by one to form the voltage section V2b of the amplified voltage signal V2 in FIG. 4B; that is to say, the voltage section V2b of the amplified voltage signal V2 in FIG. 4B is the same with the voltage section V1b of the voltage signal V1 in FIG. 4A.

Then, the analog-digital converter ADC will convert the amplified voltage signal V2 into the digital signal V3 and output the digital signal V3 to the digital gain stage 32. The gain control module 34 will also adjust three digital magnifications used by the digital gain stage 32 to amplify the three voltage sections V3a˜V3c of the digital signal V3 according to the three comparing results to form three voltage sections V4a˜V4c of the amplified digital signal V4 respectively. Since the voltage sections V3a and V3c of the digital signal V3 are already twice as large as the voltage sections V1a and V1c of the voltage signal V1, the digital gain stage 32 only needs to amplifies the voltage sections V3a and V3c of the digital signal V3 by one to form the voltage sections V4a and V4c of the amplified digital signal V4 in FIG. 4C; that is to say, the voltage sections V4a and V4c of the amplified digital signal V4 are equal to the voltage sections V3a and V3c of the digital signal V3. As to the voltage section V3b of the digital signal V3, since the voltage section V3b of the digital signal V3 is only amplified by one, the digital gain stage 32 will amplify the voltage section V3b of the digital signal V3 by two to form the voltage section V4b of the amplified digital signal V4 in FIG. 4C to compensate the decreased magnification of the analog gain stage 30.

Comparing FIG. 4C with FIG. 4A, it can be found that the three voltage sections V4a˜V4c of the amplified digital signal V4 are twice as large as the three voltage sections V1a˜V1c of the voltage signal V1; therefore, it can maintain equivalent gain magnification the same with the fixed magnification used by the sensing circuit structure in the prior art. In addition, as shown in FIG. 4B, since the voltage section V2b of the amplified voltage signal V2 in FIG. 4B is the same with the voltage section V1b of the voltage signal V1 in FIG. 4A, the output saturation of the analog-digital converter ADC can be effectively avoided.

Another embodiment of the invention is a touch signal gain control method. In this embodiment, the touch signal gain control method is applied in a touch sensing apparatus including an analog-digital converter. Please refer to FIG. 5. FIG. 5 illustrates a flowchart of the touch signal gain control method in this embodiment.

As shown in FIG. 5, the touch signal gain control method includes the following steps. In the step S10, the method generates a comparing result according to a voltage signal inputted to the analog-digital converter and an input threshold of the analog-digital converter. In the step S12, the method amplifies the voltage signal in an analog magnification according to the comparing result to form an amplified voltage signal not over the input threshold. In the step S14, the analog-digital converter converts the amplified voltage signal into a digital signal. In the step S16, the method amplifies the digital signal in a digital magnification according to the comparing result to form an amplified digital signal. Wherein, the product of the analog magnification and the digital magnification equals to a gain ratio of the amplified digital signal and the voltage signal.

When the comparing result generated by the step S10 is that the product of the voltage signal inputted to the analog gain stage and a default analog magnification is over the input threshold of the analog-digital converter, the method will decrease the default analog magnification to the analog magnification according to the comparing result, so that the amplified voltage signal generated in the step S12 will be not over the input threshold. Wherein, the default analog magnification is the gain ratio of the amplified digital signal and the voltage signal.

Another characteristic of the invention is to dynamically adjust the magnifications of different sections of the input signal respectively. For example, if the voltage signal inputted to the analog gain stage is divided into a plurality of voltage sections, the touch signal gain control method will generate a plurality of comparing results corresponding to the plurality of voltage sections of the voltage signal respectively, and then amplify the plurality of voltage sections of the voltage signal in a plurality of analog magnifications according to the plurality of comparing results to form a plurality of sections of the digital signal, and then amplify the plurality of voltage sections of the digital signal in a plurality of digital magnifications according to the plurality of comparing results to form a plurality of sections of the amplified digital signal. For each section, the product of the analog magnification and the digital magnification will be the same and equal to the gain ratio of the section of the amplified digital signal and the section of the voltage signal.

Compared to the output saturation problem easily occurred in the sensing circuit structure using fixed magnification of the prior art, the touch signal gain control apparatus and method of the invention uses the comparator to detect the input voltage signal, once the input voltage signal is over the input threshold, the analog magnification of the analog gain stage will be automatically decreased to prevent the output saturation of the analog-digital converter, and then the digital gain stage will be used to amplify the digital signal outputted by the analog-digital converter to compensate the decreased magnification of the analog gain stage. Therefore, the touch signal gain control apparatus and method of the invention can not only effectively improve the output saturation problem of the analog-digital converter in the prior art, but also maintain equivalent gain magnification the same with that of the sensing circuit structure using fixed magnification in the prior art without sacrificing the real magnification of the gain stage.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

1. A touch signal gain control apparatus, applied in a touch sensing apparatus comprising an analog-digital converter and coupled to an input terminal and an output terminal of the analog-digital converter respectively, the touch signal gain control apparatus comprising:
an analog gain stage, coupled to the input terminal of the analog-digital converter;
a digital gain stage, coupled to the output terminal of the analog-digital converter;
a gain control module, coupled to the analog gain stage and the digital gain stage respectively; and
a comparing module, coupled between the input terminal of the analog-digital converter and the gain control module;
wherein when the comparing module generates a comparing result according to a voltage signal inputted to the analog gain stage and an input threshold of the analog-digital converter, the gain control module controls the analog gain stage to amplify the voltage signal in an analog magnification according to the comparing result to form an amplified voltage signal not over the input threshold, and then the analog-digital converter converts the amplified voltage signal into a digital signal, the gain control module controls the digital gain stage to amplify the digital signal in a digital magnification according to the comparing result to form an amplified digital signal, wherein the product of the analog magnification and the digital magnification equals to a gain ratio of the amplified digital signal and the voltage signal.

2. The touch signal gain control apparatus of claim 1, wherein when the comparing result generated by the comparing module is that the product of the voltage signal inputted to the analog gain stage and a default analog magnification is over the input threshold of the analog-digital converter, the gain control module decreases the default analog magnification to the analog magnification according to the comparing result, so that the amplified voltage signal will be not over the input threshold.

3. The touch signal gain control apparatus of claim 2, wherein the default analog magnification is the gain ratio of the amplified digital signal and the voltage signal.

4. The touch signal gain control apparatus of claim 1, wherein the voltage signal inputted to the analog gain stage is divided into a plurality of voltage sections, the comparing module generates a plurality of comparing results corresponding to the plurality of voltage sections of the voltage signal respectively, the gain control module controls the analog gain stage to amplify the plurality of voltage sections of the voltage signal in a plurality of analog magnifications according to the plurality of comparing results to form a plurality of sections of the digital signal, the gain control module controls the digital gain stage to amplify the plurality of voltage sections of the digital signal in a plurality of digital magnifications according to the plurality of comparing results to form a plurality of sections of the amplified digital signal.

5. The touch signal gain control apparatus of claim 4, wherein the product of the analog magnification and the digital magnification is the same for each section and equals to the gain ratio of the section of the amplified digital signal and the section of the voltage signal.

6. A touch signal gain control method, applied in a touch sensing apparatus comprising an analog-digital converter, the touch signal gain control method comprising steps of:
generating a comparing result according to a voltage signal inputted to the analog-digital converter and an input threshold of the analog-digital converter;
amplifying the voltage signal in an analog magnification according to the comparing result to form an amplified voltage signal not over the input threshold;
the analog-digital converter converting the amplified voltage signal into a digital signal; and
amplifying the digital signal in a digital magnification according to the comparing result to form an amplified digital signal;
wherein the product of the analog magnification and the digital magnification equals to a gain ratio of the amplified digital signal and the voltage signal.

7. The touch signal gain control method of claim 6, wherein when the comparing result generated by the touch signal gain control method is that the product of the voltage signal inputted to the analog gain stage and a default analog magnification is over the input threshold of the analog-digital converter, the touch signal gain control method decreases the default analog magnification to the analog magnification according to the comparing result, so that the amplified voltage signal will be not over the input threshold.

8. The touch signal gain control method of claim 7, wherein the default analog magnification is the gain ratio of the amplified digital signal and the voltage signal.

9. The touch signal gain control method of claim 6, wherein the voltage signal is divided into a plurality of voltage sections, the touch signal gain control method generates a plurality of comparing results corresponding to the plurality of voltage sections of the voltage signal respectively, and amplifies the plurality of voltage sections of the voltage signal in a plurality of analog magnifications according to the plurality of comparing results to form a plurality of sections of the digital signal, and amplifies the plurality of voltage sections of the digital signal in a plurality of digital magnifications according to the plurality of comparing results to form a plurality of sections of the amplified digital signal.

10. The touch signal gain control method of claim 9, wherein the product of the analog magnification and the digital magnification is the same for each section and equals to the gain ratio of the section of the amplified digital signal and the section of the voltage signal.
